(19) United States
(12) Patent Application Publication
(10) Pub. No.: US 2025/0318229 A1
(43) Pub. Date: Oct. 9, 2025

(54) BUFFER STRUCTURE WITH INTERLAYER BUFFER LAYERS FOR HIGH VOLTAGE DEVICE

(71) Applicant: Taiwan Semiconductor Manufacturing Company, Ltd., Hsinchu (TW)

(72) Inventors: Chi-Ming Chen, Zhubei City (TW); Kuei-Ming Chen, New Taipei City (TW)

(21) Appl. No.: 19/243,080

(22) Filed: Jun. 19, 2025

Related U.S. Application Data
(63) Continuation of application No. 18/329,881, filed on Jun. 6, 2023.
(60) Provisional application No. 63/483,023, filed on Feb. 3, 2023.

(51) Int. Cl. H10D 62/815; H01L 21/02; H10D 30/01; H10D 30/47; H10D 62/85

(52) U.S. Cl. CPC H10D 62/8171; H01L 21/02458; H01L 21/02507; H01L 21/0251; H01L 21/0254; H10D 30/015; H10D 30/475; H10D 62/8503

(57) ABSTRACT

Various embodiments of the present disclosure are directed towards an integrated chip a semiconductor device including a plurality of superlattice layers disposed over a substrate. The plurality of superlattice layers include a first superlattice layer overlying a second superlattice layer. A channel layer overlies the plurality of superlattice layers. An active layer overlies the channel layer. A first interlayer buffer layer is disposed directly between the first superlattice layer and the second superlattice layer. The first interlayer buffer layer comprises a first density of dislocations greater than a second density of dislocations in the first superlattice layer.

### REFERENCE TO RELATED APPLICATIONS

This Application is a Continuation of U.S. application Ser. No. 18/329,881, filed on Jun. 6, 2023, which claims the benefit of U.S. Provisional Application No. 63/483,023, filed on Feb. 3, 2023. The contents of the above-referenced Patent Applications are hereby incorporated by reference in their entirety.

### BACKGROUND

Modern day integrated chips comprise millions or billions of semiconductor devices formed on a semiconductor substrate (e.g., silicon). Integrated chips (ICs) may use many different types of transistor devices, depending on an application of an IC. In recent years, the increasing market for automotive high voltage devices has resulted in a significant increase in the use of high voltage transistor devices. Thus, high electron mobility transistor (HEMT) devices have been receiving increased attention due to high electron mobility and wide band gaps compared to silicon-based semiconductor devices. Such high electron mobility and wide band gaps allow improved performance (e.g., fast switching speeds, low noise) and high temperature applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a high voltage device comprising a plurality of interlayer buffer layers stacked alternatingly with a plurality of superlattice layers.

FIG. 2 illustrates a cross-sectional view of other embodiments of a high voltage device comprising a plurality of interlayer buffer layers stacked alternatingly with a plurality of superlattice layers.

FIG. 3 illustrates a cross-sectional view of yet other embodiments of a high voltage device comprising a plurality of interlayer buffer layers stacked alternatingly with a plurality of superlattice layers.

FIG. 4 illustrates a cross-sectional view of some other embodiments of the high voltage device of FIG. 3, in which the interlayer buffer layers respectively comprise a first buffer layer vertically stacked with a second buffer layer.

FIG. 5 illustrates a cross-sectional view of some other embodiments of the high voltage device of FIG. 3, in which the plurality of interlayer buffer layers comprise a lower interlayer buffer layer abutting a grated buffer layer and an upper interlayer buffer layer abutting a high resistivity buffer layer.

FIG. 6 illustrates a cross-sectional view of yet other embodiments of the high voltage device of FIG. 3.

FIG. 7 illustrates a cross-sectional view of further embodiments of the high voltage device of FIG. 3.

FIGS. 8-24 illustrate cross-sectional views of some embodiments of a method for forming a high voltage device including a plurality of interlayer buffer layers stacked alternatingly with a plurality of superlattice layers.

FIG. 25 illustrates a flowchart of some embodiments of a method for forming a high voltage device including a plurality of interlayer buffer layers stacked alternatingly with a plurality of superlattice layers.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A high electron mobility transistor (HEMT) device (e.g., a GaN transistor) may include an epitaxial stack arrange over a substrate (e.g., a silicon substrate). The epitaxial stack may include an aluminum nitride (AlN) seed layer over the substrate, a buffer structure over the AlN seed layer, a channel layer (e.g., comprising GaN) on the buffer structure, and an active layer (e.g., comprising aluminum gallium nitride (AlₓGa₁₋ₓN)) on the channel layer. A heterojunction is defined between the channel layer and the active layer such that a two-dimensional electron gas (2-DEG) forms in the channel layer. The buffer structure is configured to compensate for a lattice mismatch between the substrate and the channel layer. For example, the buffer structure includes a graded lower buffer layer, a plurality of superlattice layers, and a high resistivity buffer layer stacked in that order.

A challenge with the foregoing HEMT device is a tensile stress induced and/or produced by one or more layers in the epitaxial stack. For example, the high resistivity buffer layer comprises one or more dopants (e.g., carbon dopants) to achieve high resistivity. However, the one or more dopants may induce tensile stress that may lead to defects (e.g., cracks, dislocations, etc.) in the channel layer and/or the high resistivity buffer layer. Further, the plurality of superlattice layers respectively comprise a pair of semiconductor layers that are lattice mismatched. For example, the pair of semiconductor layers includes an AlN layer stacked with an AlGaN layer (or a GaN layer). The plurality of superlattice layers are configured to reduce tensile stress in the overlying channel layer (e.g., as induced by the high resistivity buffer layer). Nevertheless, as a number of epitaxial layers in the epitaxial stack increases and/or an overall thickness of the epitaxial stack is increased, cracking and/or dislocations may occur in the channel layer. This, in part, may occur due to an accumulated tensile stress across different layers in the epitaxial stack during fabrication. In an effort to limit cracking and/or poor crystal quality in the channel layer a total thickness of the epitaxial stack may be limited to less than about 5 micrometers. As a result of the limited thickness of the epitaxial stack, a soft breakdown voltage of the HEMT device may be limited or decreased.

Further, the epitaxial stack may be formed at a relatively high temperature. After fabrication of the epitaxial stack a cool down process may be performed to reduce a temperature of the chamber that the epitaxial stack is disposed in from the high temperature to a low temperature (e.g., to room temperature). Due to a lattice mismatch and/or a coefficient of temperature expansion (CTE) mismatch between the channel layer and the substrate, a tensile stress on the channel layer and/or other layers of the epitaxial stack may increase during the cool down process. This may cause cracking and/or dislocations in the channel layer during and/or after the cool down process, thereby mitigating a reliability and overall performance of the HEMT device.

Various embodiments of the present disclosure are directed towards a high voltage device comprising interlayer buffer layers configured to reduce tensile stress in an epitaxial stack of the high voltage device and a corresponding method of fabrication. The high voltage device includes an epitaxial stack overlying a substrate. The epitaxial stack includes a plurality of superlattice layers over the substrate, a channel layer over the plurality of superlattice layers, and an active layer over the channel layer. Further, the plurality of interlayer buffer layers are disposed between adjacent superlattice layers. The interlayer buffer layers are formed at a lower temperature than the superlattice layers and are configured to reduce undesired stress (e.g., high tensile stress) in one or more of the superlattice layers and/or the channel layer. Reduction of the undesired stress decreases cracking and/or dislocations in the channel layer and facilitates increasing an overall thickness of the epitaxial stack. Accordingly, an overall performance and reliability of the high voltage device may be increased.

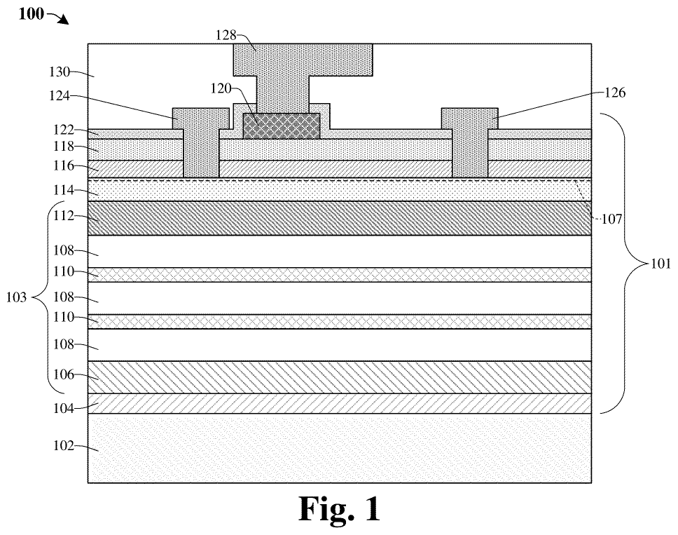

FIG. 1 illustrates a cross-sectional view 100 of some embodiments of a high voltage device comprising interlayer buffer layers disposed between adjacent superlattice layers.

The high voltage device comprises an epitaxial stack 101 disposed on a substrate 102. The substrate 102 may, for example, be or comprise silicon carbide, silicon, sapphire, or the like. Further, the substrate 102 has a crystalline orientation of (111), but other orientations are amenable. In some embodiments, the substrate 102 comprises silicon and has a crystalline orientation of (111). In various embodiments, the epitaxial stack 101 comprises a seed layer 104, a buffer structure 103, a channel layer 114, a spacer layer 116, an active layer 118, and a doped semiconductor structure 120 stacked in that order. The seed layer 104 is arranged over the substrate 102 and is configured to facilitate growth of one or more layers of the buffer structure 103. The seed layer 104 may, for example, be or comprise a group III-V material, such as aluminum nitride or some other suitable material. The high voltage device may be configured as a high electron mobility transistor (HEMT).

In various embodiments, the buffer structure 103 comprises a graded buffer layer 106, a plurality of superlattice layers 108, a plurality of interlayer buffer layers 110, and a high resistivity buffer layer 112. The graded buffer layer 106 overlies the seed layer 104. In various embodiments, the graded buffer layer 106 comprises multiple layers (not shown) with increasing or decreasing amounts of an element common to the layers, where the relative amounts of the element change to reduce lattice contacts of the multiple layers as a distance from the substrate 102 increases. For example, the multiple layers may each comprise a group III-V material, such as aluminum gallium nitride (AlₓGa₁₋ₓN, where x is within a range of about 0.1-0.8).

The plurality of superlattice layers 108 overlie the graded buffer layer 106. In various embodiments, the plurality of superlattice layers 108 respectively comprise one or more pairs of semiconductor layers, where each pair of semiconductor layers comprise at least a first semiconductor layer stacked with a second semiconductor layer. Lattice constants of the first and second semiconductor layers are mismatched such that, for example, the pair of semiconductor layers collectively produce a compressive force. In various embodiments, the first semiconductor layer comprises gallium nitride (GaN) or Al_{y}GaN_{1-y} (where y is about 0-0.5), and the second semiconductor layer comprises aluminum nitride (AlN). In some embodiments, a lattice constant of the first semiconductor layer is greater than a lattice constant of the second semiconductor layer, where a compressive force produced by the first semiconductor layer is greater than a tensile force produced by the second semiconductor layer. As a result, the first and second semiconductor layers collectively produce a compressive force. Further, the superlattice layers 108 each comprise one or more dopants (e.g., carbon) that increase a resistivity of the superlattice layers 108. In various embodiments, the plurality of superlattice layers 108 are formed at a relatively high temperature (e.g., within a range of about 950 to 1,200 degrees Celsius) such that the superlattice layers 108 have a high crystalline quality and a low density of dislocations (e.g., edge dislocation(s), screw dislocation(s), etc.).

The high resistivity buffer layer 112 overlies the plurality of superlattice layers 108. The high resistivity buffer layer 112 comprises a group III-V material such as, for example, GaN doped with one or more dopants (e.g., carbon). The one or more dopants increase the resistivity of the high resistivity buffer layer 112, may increase a compressive force generated by the high resistivity buffer layer 112, and/or may decrease leakage in the high resistivity buffer layer 112.

The channel layer 114 of the epitaxial stack 101 overlies the high resistivity buffer layer 112. In some embodiments, the channel layer 114 comprises a group III-V material, such as GaN, undoped GaN, or the like. The spacer layer 116 overlies the channel layer 114 and comprises a group III-V material, such as AlN. The active layer 118 overlies the spacer layer 116. In some embodiments, the active layer 118 comprises a group III-V material such as AlGaN having a band gap different from that of the channel layer 114. In various embodiments, by virtue of a difference in band gaps between the spacer and/or active layers 116, 118 and the channel layer 114, a heterojunction forms between the channel layer 114 and the active layer 118. In some embodiments, the channel layer 114 comprises a two-dimensional electron gas (2-DEG) 107 proximate to the heterojunction. In various embodiments, the 2-DEG 107 comprises high mobility electrons that are free to move within the channel layer 114.

The doped semiconductor structure 120 overlies the active layer 118. In various embodiments, the doped semiconductor structure 120 comprises GaN having a first doping type (e.g., p-type). A passivation layer 122 overlies the epitaxial stack 101. A dielectric structure 130 overlies the passivation layer 122. A gate electrode 128 overlies the doped semiconductor structure 120 and source/drain electrodes 124, 126 are disposed on opposing sides of the gate electrode 128. In some embodiments, the source/drain electrodes 124, 126 extend through the spacer layer 116 and the active layer 118 to contact the channel layer 114. In various embodiments, by suitably biasing the gate electrode 128 and/or the source/drain electrodes 124, 126, the active layer 118 selectively provides or removes electrons to or from the 2-DEG 107.

In various embodiments, one or more layers of the epitaxial stack 101 (e.g., layers comprising GaN such as the superlattice layers 108, the high resistivity buffer layer 112, the channel layer 114, etc.) may produce and/or comprise a tensile stress that increases and/or accumulates during fabrication of the epitaxial stack 101. For example, during fabrication of the epitaxial stack 101, the one or more layers of the epitaxial stack 101 (e.g., the superlattice layers 108, the high resistivity buffer layer 112, the channel layer 114, etc.) may each be deposited and/or grown at a relatively high temperature (e.g., greater than 900 degrees Celsius) to have a relatively low initial tensile stress. After depositing and/or growing the epitaxial stack 101, a cool down process is performed where a temperature of the epitaxial stack 101 is reduced from the high temperature to a low temperature (e.g., about 20 degrees Celsius). By virtue of a lattice mismatch and/or a coefficient of thermal expansion (CTE) mismatch between the one or more layers of the epitaxial stack 101 (e.g., layers comprising GaN) and the substrate 102 (e.g., comprising silicon), the initial tensile stress of each of the one or more layers is prone to increase during and/or after the cool down process.

In various embodiments, the interlayer buffer layers 110 are configured to decrease a tensile stress in the superlattice layers 108, the high resistivity buffer layer, and/or the channel layer 114. For example, the interlayer buffer layers 110 are configured to induce and/or maintain a relatively low initial tensile force in the superlattice layers 108, the high resistivity buffer layer, and/or the channel layer 114, where an accumulation and/or an increase of the initial tensile force is mitigated during the fabrication process (e.g., is mitigated during the cool down process). This occurs, in part, because the interlayer buffer layers 110 are formed at a relatively low formation temperature (e.g., within a range of about 600 to 950 degrees Celsius) and may comprise a high density of dislocations (e.g., edge dislocation(s), screw dislocation(s), etc.) across the crystal structure of the interlayer buffer layers 110. For example, the interlayer buffer layers 110 have a greater density of dislocations than the plurality of superlattice layers 108. In some embodiments, the high density of dislocations, thickness, material, and/or locations of the interlayer buffer layers 110 induces and/or maintains the initial weak tensile force in the superlattice layers 108, the high resistivity buffer layer, and/or the channel layer 114 while mitigating accumulation of tensile stress in the epitaxial stack 101 during fabrication. As a result, an overall tensile stress of the buffer structure 103 is reduced while the compressive force on the channel layer 114 is minimally affected or maintained, such that the channel layer 114 is advantageously strained. Therefore, an overall thickness of the epitaxial stack 101 may be increased (e.g., to above 5 um) while mitigating cracking in layers of the epitaxial stack 101, thereby increasing an overall performance and reliability of the high voltage device.

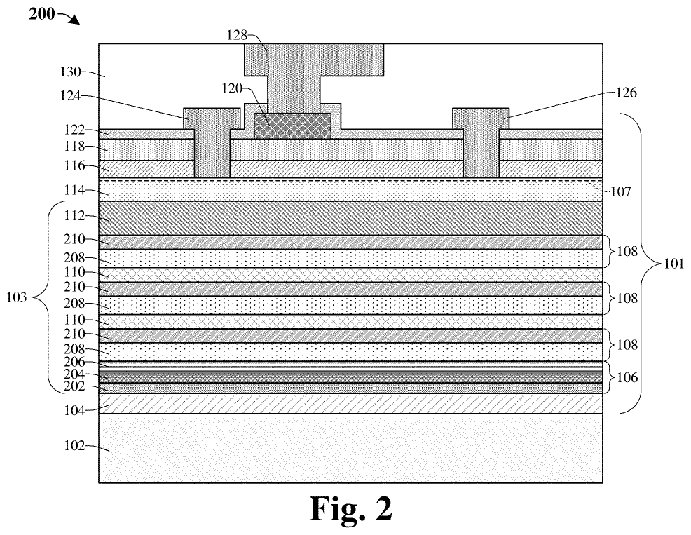

FIG. 2 illustrates a cross-sectional view 200 of some other embodiments of a high voltage device comprising interlayer buffer layers disposed between adjacent superlattice layers.

In various embodiments, the high voltage device comprises an epitaxial stack 101 disposed on a substrate 102. In some embodiments, the substrate 102 comprises silicon and has a crystalline orientation of (111). In further embodiments, the substrate 102 has a thickness of about 1 millimeter (mm) or some other suitable value. The epitaxial stack 101 comprises a seed layer 104, a buffer structure 103, a channel layer 114, a spacer layer 116, an active layer 118, and a doped semiconductor structure 120 stacked in that order. The seed layer 104 overlies the substrate 102 and is configured to facilitate growth of one or more layers of the buffer structure 103. Further, the seed layer 104 may be configured to isolate the substrate 102 from an overlying active area of the high voltage device. The seed layer 104 may, for example, be or comprise AlN or some other suitable material. In various embodiments, a thickness of the seed layer 104 is within a range of about 100 to 300 nanometers (nm) or some other suitable value.

The buffer structure 103 comprises a graded buffer layer 106, a plurality of superlattice layers 108, a plurality of interlayer buffer layers 110, and a high resistivity buffer layer 112. The graded buffer layer 106 overlies the seed layer 104. In various embodiments, the graded buffer layer 106 comprises a first graded buffer layer 202, a second graded buffer layer 204, and a third graded buffer layer 206. The first, second, and third graded buffer layers 202-206 may each comprise aluminum gallium nitride (AlₓGa₁₋ₓN, where x is within a range of about 0.1-0.8), where a concentration of aluminum in the first, second, and third graded buffer layers 202-206 decreases from the first graded buffer layer 202 to the third graded buffer layer 206. For example, the first graded buffer layer 202 may comprise Al_{0.75}Ga_{0.25}N, the second graded buffer layer 204 may comprise Al_{0.5}Ga_{0.5}N, and the third graded buffer layer 206 may comprise Al_{0.25}Ga_{0.75}N. It will be appreciated that the first, second, and third graded buffer layers 202-206 comprising other concentrations of elements is within the scope of the present disclosure. In further embodiments, a thickness of the graded buffer layer 106 is within a range of about 100 to 500 nm or some other suitable value.

The plurality of superlattice layers 108 are alternatingly stacked with the plurality of interlayer buffer layers 110 and overlie the graded buffer layer 106. In some embodiments, the plurality of superlattice layers 108 respectively comprise one or more pairs of semiconductor layers 208, 210 that respectively comprise a first semiconductor layer 208 stacked with a second semiconductor layer 210. In various embodiments each superlattice layer 108 may include about 10 to 500 pairs of the first and second semiconductor layers 208, 210 (not shown). In such embodiments, an individual interlayer buffer layer 110 may be disposed between adjacent pairs of the first and second semiconductor layers 208, 210. The first semiconductor layer 208 may, for example, be or comprise GaN, Al_{y}GaN_{1-y} (where y is about 0-0.5), or some other suitable group III-V material. The second semiconductor layer 210 may, for example, be or comprise AlN or some other suitable group III-V material. In yet further embodiments, the first semiconductor layer 208 may be disposed on top of the second semiconductor layer 210 (not shown). In various embodiments, a thickness of the first semiconductor layer 208 is within a range of about 10 to 50 nm or some other suitable value. In further embodiments, a thickness of the second semiconductor layer 210 is within a range of about 1 to 10 nm or some other suitable value. In yet further embodiments, the thickness of the first semiconductor layer 208 is greater than the thickness of the second semiconductor layer 210. A thickness of each superlattice layer 108 may, for example, be about 1.5 um, within a range of about 0.5 to 10 nm, or some other suitable value.

The superlattice layers 108 each comprise one or more dopants, such as, for example, carbon that increases a resistivity of the superlattice layers 108 and/or increases a collective compressive forced produced by the superlattice layers 108. In some embodiments, a concentration of the one or more dopants (e.g., carbon) in the superlattice layers 108 is greater than about 1 e 19 cm⁻³, within a range of about 1 e 19 cm⁻³ to 4 e 19 cm⁻³, is about 3 e 19 cm⁻³, or some other suitable value. In various embodiments, both the first semiconductor layer 208 and the second semiconductor layer 210 comprise the one or more dopants (e.g., carbon) with the aforementioned concentration. The superlattice layers 108 are grown at a relatively high temperature (e.g., greater than 950° C. or the like), such that the superlattice layers 108 have a high-quality crystalline structure with a relatively density of dislocations (e.g., edge dislocation(s), screw dislocation(s), etc.). Accordingly, the superlattice layers 108 are configured as buffer layers with high-quality crystalline structures that mitigate negative effects (e.g., cracking) due to a lattice and/or CTE mismatch between the channel layer 114 and the substrate 102.

The high resistivity buffer layer 112 is disposed between the plurality of superlattice layers 108 and the channel layer 114. The high resistivity buffer layer 112 comprises GaN doped with one or more dopants (e.g., carbon). A concentration of the one or more dopants (e.g., carbon) within the high resistivity buffer layer 112 is, for example, greater than about 8 e 18 cm⁻³ or some other suitable value. In some embodiments, the concentration of the one or more dopants within the high resistivity buffer layer 112 is less than the concentration of the one or more dopants within the superlattice layers 108. In various embodiments, a thickness of the high resistivity buffer layer 112 is within a range of about 0.5 to 1.5 um or some other suitable value. The channel layer 114 overlies the high resistivity buffer layer 112. The channel layer 114 may, for example, be or comprise GaN, undoped GaN, or the like. In some embodiments, a thickness of the channel layer 114 is within a range of about 0.2 to 1 um or some other suitable value. The spacer layer 116 overlies the channel layer 114. The spacer layer 116 may, for example, be or comprise AlN or the like. In some embodiments, a thickness of the spacer layer 116 is about 1 nm, within a range of about 0.5 to 1.5 nm, or some other suitable value. The active layer 118 overlies the spacer layer 116. In some embodiments, the active layer 118 comprises Al_{z}Ga_{1-z}N (where z is within a range of about 0.1-0.5) or some other suitable material. In various embodiments, a thickness of the active layer 118 is within a range of about 15 to 30 nm or some other suitable value.

The doped semiconductor structure 120 overlies the active layer 118. In various embodiments, the doped semiconductor structure 120 comprises GaN including a first dopant (e.g., magnesium) having a first doping type (e.g., p-type). In such embodiments, a concentration of the first dopant within the doped semiconductor structure 120 may be within a range of about 1 e 19 cm⁻³ to 5 e 19 cm⁻³, or some other suitable value. In yet further embodiments, the doped semiconductor structure 120 comprises two or more layers (not shown). For example, the doped semiconductor structure 120 may include a first group III-V material layer (e.g., comprising GaN) comprising the first dopant (e.g., magnesium) having the first doping type (e.g., p-type) and a second group III-V material layer (comprising GaN) comprising a second dopant (e.g., silicon) having a second doping type (e.g., n-type), where the second group III-V material layer overlies the first group III-V material layer (not shown). In such embodiments, a concentration of the first dopant (e.g., magnesium) within the first group III-V material layer is within a range of about 1 e 19 cm⁻³ to 5 e 19 cm⁻³, and/or a concentration of the second dopant (e.g., silicon) within the second group III-V material layer is within a range of about 1 e 15 cm⁻³ to 1 e 17 cm⁻³In various embodiments, a thickness of the doped semiconductor structure 120 is within a range of about 30 to 100 nm, within a range of about 60 to 200 nm, or some other suitable value.

A passivation layer 122 overlies the epitaxial stack 101. The passivation layer 122 may, for example, be or comprise silicon nitride or some other suitable material. In some embodiments, a thickness of the passivation layer 122 is within a range of about 100 to 500 angstroms or some other suitable value. A dielectric structure 130 overlies the passivation layer 122. The dielectric structure 130 may, for example, be or comprise silicon dioxide or some other suitable material. A gate electrode 128 overlies the doped semiconductor structure 120. The gate electrode 128 may, for example, be or comprise titanium nitride, tantalum nitride, aluminum, some other conductive material, or any combination of the foregoing. Source/drain electrodes 124, 126 are disposed on opposing sides of the gate electrode 128. In some embodiments, the source/drain electrodes 124, 126 extend through the spacer layer 116 and the active layer 118 to contact the channel layer 114. The source/drain electrodes 124, 126 may, for example, be or comprise titanium, tantalum, a silicide (e.g., titanium silicide), aluminum, some other conductive material, or any combination of the foregoing.

The interlayer buffer layers 110 are stacked between adjacent superlattice layers in the plurality of superlattice layers 108. In various embodiments, the interlayer buffer layers 110 comprise AlN, AlGaN, some other group III-V material, or any combination of the foregoing. In some embodiments, the interlayer buffer layers 110 comprise a same first material (e.g., AlN) as the seed layer 104, the second semiconductor layer 210, and/or the spacer layer 116. In yet further embodiments, the interlayer buffer layers 110 comprise a same second material (e.g., AlGaN) as the graded buffer layer 106, the first semiconductor layer 208, and/or the active layer 118. A thickness of the interlayer buffer layers 110 is, for example, within a range of about 5 to 50 nm or some other suitable value. In some embodiments, the interlayer buffer layers 110 comprise one or more dopants (e.g., carbon) with a concentration of about 3 e 19 cm⁻³, greater than about 1 e 19 cm⁻³, within a range of about 2 e 19 cm⁻³ to 4 e 19 cm⁻³, or some other suitable value. In some embodiments, the interlayer buffer layers 110 may be referred to as tensile stress relief layers.

The interlayer buffer layers 110 are formed at a relatively low temperature (e.g., within a range of about 600 to 950 degrees Celsius). In some embodiments, as a result of being formed at the relatively low temperature the interlayer buffer layers 110 have a high density of dislocations. For example, the interlayer buffer layers 110 have a greater number of dislocations per unit area or unit volume compared to a number of dislocations per unit area or unit volume of the superlattice layers 108. By virtue of the interlayer buffer layers 110 being formed at the relatively low temperature (and comprising the high density of dislocations), undesired stress (e.g., tensile stress) in the superlattice layers 108, the high resistivity buffer layer 112, the channel layer 114, and/or the doped semiconductor structure 120 is reduced. This, in part, mitigates cracking in the epitaxial stack 101, thereby increasing an overall performance of the high voltage device. In various embodiments, the interlayer buffer layers 110 comprising the one or more dopants mitigates negative effects (e.g., due to dangling bonds) of the interlayer buffer layers 110 being formed at the relatively low temperatures. For example, the one or more dopants increases a resistivity of each interlayer buffer layer 110, thereby decreasing leakage in the high voltage device.

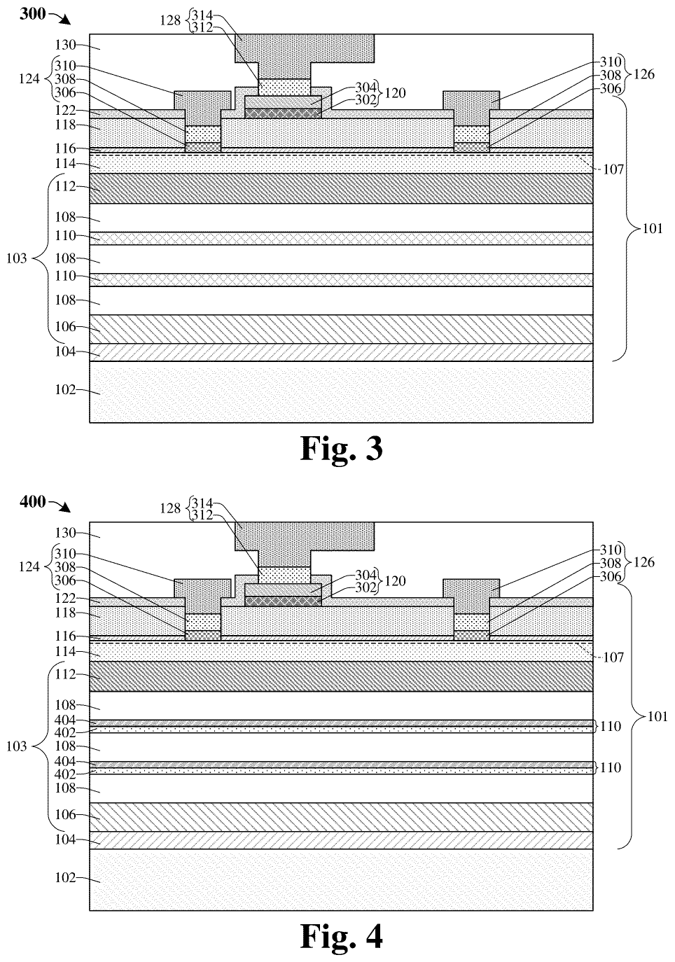

FIG. 3 illustrates a cross-sectional view 300 of some other embodiments of the high voltage device of FIG. 2, in which the doped semiconductor structure 120 comprises a first doped layer 302 stacked with a second doped layer 304. In some embodiments, the first doped layer 302 comprises GaN comprising a first dopant (e.g., magnesium) having a first doping type (e.g., p-type) and the second doped layer 304 comprises GaN comprising a second dopant (e.g., silicon) having a second doping type (e.g., n-type). In various embodiments, a concentration of the first dopant (e.g., magnesium) within the first doped layer 302 is within a range of about 1 e 19 cm⁻³ to 5 e 19 cm⁻³. In some embodiments, a concentration of the second dopant (e.g., silicon) within the second doped layer 304 is within a range of about 1 e 15 cm⁻³ to 1 e 17 cm⁻³. In some embodiments, thicknesses of the first and second doped layers 302, 304 are respectively within a range of about 30 to 100 nm or some other suitable value.

Further, the source/drain electrodes 124, 126 respectively comprise a silicide layer 306, a first source/drain electrode layer 308, and a second source/drain electrode layer 310. Further, the gate electrode 128 comprises a first gate electrode layer 312 and a second gate electrode layer 314. The silicide layer 306 may, for example, be or comprise titanium silicide, tantalum silicide, nickel silicide, some other conductive material, or any combination of the foregoing. The first source/drain electrode layer 308 may, for example, be or comprise titanium, tantalum, nickel, some other metal, or any combination of the foregoing. In some embodiments, a thickness of the first source/drain electrode layer 308 is within a range of about 50 to 300 angstroms or some other suitable value. The second source/drain electrode layer 310 may, for example, be or comprise aluminum, tungsten, some other metal, or any combination of the foregoing. In various embodiments, a thickness of the second source/drain electrode layer 310 is within a range of about 1,000 to 2,000 angstroms or some other suitable value. The first gate electrode layer 312 may, for example, be or comprise titanium nitride, tantalum nitride, another conductive material, or any combination of the foregoing. In various embodiments, a thickness of the first gate electrode layer 312 is within a range of about 50 to 2,000 angstroms or some other suitable value. The second gate electrode layer 314 may, for example, be or comprise aluminum, tungsten, some other metal, or any combination of the foregoing. In some embodiments, a thickness of the second gate electrode layer 314 is within a range of about 2,000 to 5,000 angstroms or some other suitable value.

FIG. 4 illustrates a cross-sectional view 400 of some other embodiments of the high voltage device of FIG. 3, in which the interlayer buffer layers 110 respectively comprise a first buffer layer 402 vertically stacked with a second buffer layer 404. The first buffer layer 402 may, for example, be or comprise AlN and the second buffer layer 404 may, for example, be or comprise AlGaN. In various embodiments, the first and second buffer layers 402, 404 are each grown at a relatively low temperature (e.g., less than about 950 degrees Celsius), such that the first and second buffer layers 402, 404 respectively comprise a high concentration of dislocations and/or a high concentration of dangling bonds. In some embodiments, the first and second buffer layers 402, 404 respectively comprise one or more dopants (e.g., carbon) having a concentration of about 3 e 19 cm⁻³, greater than about 1 e 19 cm⁻³, within a range of about 2 e 19 cm⁻³ to 4 e 19 cm⁻³, or some other suitable value. In further embodiments, thicknesses of the first and second buffer layers 402, 404 are respectively within a range of about 5 to 50 nm or some other suitable value.

FIG. 5 illustrates a cross-sectional view 500 of some other embodiments of the high voltage device of FIG. 3, in which the plurality of interlayer buffer layers 110 comprises a lower interlayer buffer layer 1101 disposed on a top surface of the graded buffer layer 106 and an upper interlayer buffer layer 110u disposed on a bottom surface of the high resistivity buffer layer 112.

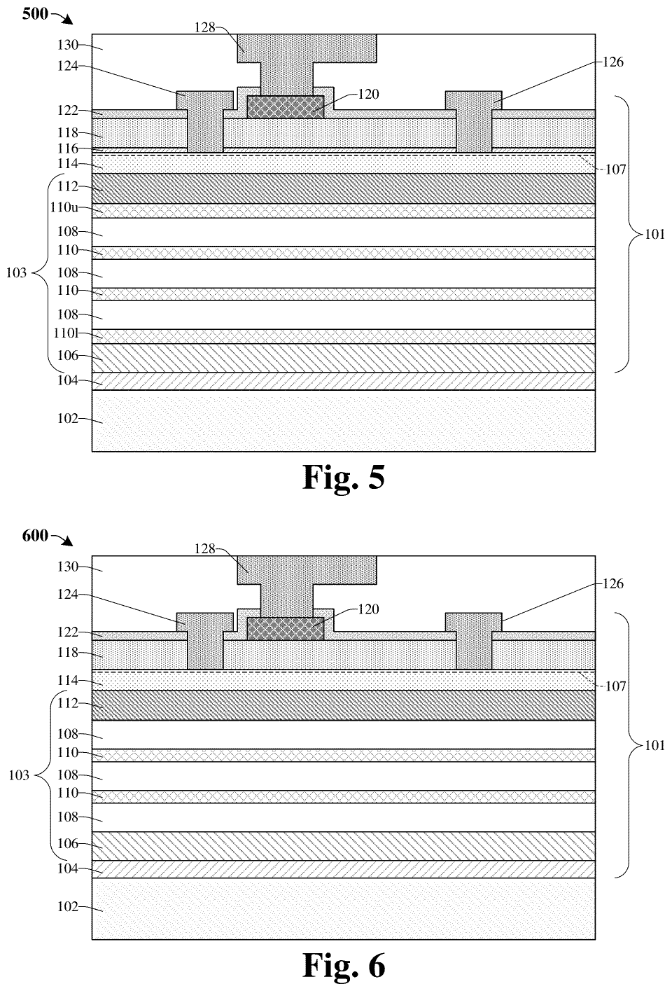

FIG. 6 illustrates a cross-sectional view 600 of further embodiments of the high voltage device of FIG. 3, in which the spacer layer (116 of FIG. 3) is omitted. In such embodiments, the active layer 118 directly contacts the channel layer 114.

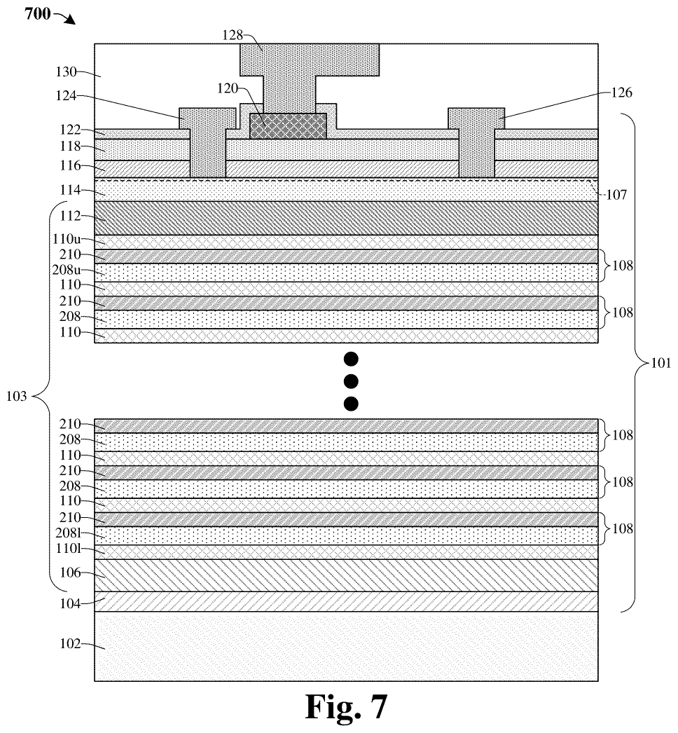

FIG. 7 illustrates a cross-sectional view 700 of yet further embodiments of the high voltage device of FIG. 3, in which the buffer structure 103 comprises any number of superlattice layers 108 and/or interlayer buffer layers 110.

In various embodiments, each superlattice layer 108 comprises about 10 to 500 pairs of the first and second semiconductor layers 208, 210 (not shown). In such embodiments, an individual interlayer buffer layer 110 is disposed between each adjacent pair of first and second semiconductor layers 208, 210. In various embodiments, a temperature of formation of each of the interlayer buffer layers 110 increases as a distance from the substrate 102 increases. In such embodiments, a density of dislocations in the interlayer buffer layers 110 decreases as a distance from the substrate 102 increases. For example, the lower interlayer buffer layer 1101 may be formed at about 600 degrees Celsius and the upper interlayer buffer layer 110u may be formed at about 950 degrees Celsius, such that the lower interlayer buffer layer 1101 has a higher density of dislocations than the upper interlayer buffer layer 110u. This, in part, mitigates leakage in interlayer buffer layers 110 in a closer proximity to the channel layer 114, thereby increasing an overall performance of the high voltage device. In various embodiments, a concentration of aluminum in the first semiconductor layer 208 of each superlattice layer decreases as a distance from the substrate 102 increases. For example, a lower first semiconductor layer 2081 comprises Al_{0.2}GaN_{0.8} and an upper first semiconductor layer 208u comprises GaN (i.e., is devoid of aluminum).

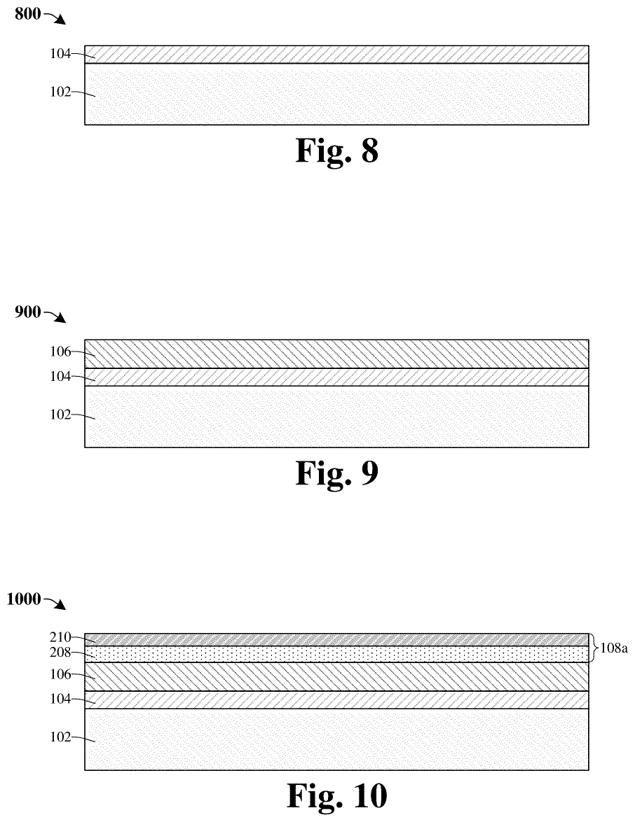

FIGS. 8-24 illustrate cross-sectional views 800-2400 of some embodiments of a method for forming a high voltage device including interlayer buffer layers disposed between adjacent superlattice layers. Although the cross-sectional views 800-2400 shown in FIGS. 8-24 are described with reference to a method, it will be appreciated that the structures shown in FIGS. 8-24 are not limited to the method but rather may stand alone separate of the method. Although FIGS. 8-24 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 800 of FIG. 8, a substrate 102 is provided and a seed layer 104 is formed over the substrate 102. The substrate 102 may, for example, be or comprise silicon carbide, silicon, sapphire, AlN, or the like. In various embodiments, the substrate 102 has a crystalline orientation of (111), but other orientations are amenable. In some embodiments, the substrate 102 comprises silicon has a crystalline orientation of (111). The seed layer 104 may be formed or grown over the substrate 102 by a metal-organic chemical vapor deposition (MOCVD), molecular beam epitaxy (MBE), another epitaxial growth process, some other suitable growth or deposition process, or any combination of the foregoing. In various embodiments, the seed layer 104 may be formed over the substrate 102 at a temperature within a range of about 850 to 1,150 degrees Celsius and under a pressure within a range of about 30 to 100 millibar (mbar). In various embodiments, the seed layer 104 is or comprises AlN or another suitable group III-V material and/or is formed to a thickness within a range of about 100 to 300 nm or some other suitable value.

As shown in cross-sectional view 900 of FIG. 9, a graded buffer layer 106 is formed over the seed layer 104. In various embodiments, the graded buffer layer 106 comprises multiple layers (e.g., as illustrated and/or described in FIG. 2) that each comprise a group III-V material, such as AlₓGa₁₋ₓN, where x is within a range of about 0.1-0.8. The multiple layers have increasing or decreasing amounts of an element common to the layers, where the relative amounts of the element change as a distance from the substrate 102 increases. A process for forming the graded buffer layer 106 includes performing one or more growth processes to sequentially form the multiple layers stacked over one another. The one or more growth processes includes a MOCVD process, an MBE process, some other suitable growth or deposition process, or any combination of the foregoing. In various embodiments, the graded buffer layer 106 is formed at a temperature within a range of about 1,000 to 1,150 degrees Celsius and under a pressure within a range of about 30 to 100 mbar. In some embodiments, the graded buffer layer 106 is formed to a thickness within a range of about 100 to 500 nm or some other suitable value.

As shown in cross-sectional view 1000 of FIG. 10, a first superlattice layer 108a is formed over the graded buffer layer 106. In various embodiments, the first superlattice layer 108a comprises one or more pairs of semiconductor layers 208, 210 that respectively comprise a first semiconductor layer 208 stacked with a second semiconductor layer 210. The first semiconductor layer 208 may, for example, be or comprise GaN, Al_{y}GaN_{1-y} (where y is about 0-0.5,about 0-0.2, or the like), or some other suitable group III-V material. The second semiconductor layer 210 may, for example be or comprise AlN or some other suitable group III-V material. In various embodiments, the first semiconductor layer 208 is formed to a thickness of about 10 to 50 nm or some other suitable value. In further embodiments, the second semiconductor layer 210 is formed to a thickness of about 1 to 10 nm or some other suitable value. In yet further embodiments, the thickness of the first semiconductor layer 208 is greater than the thickness of the second semiconductor layer 210.

In some embodiments, a process for forming the first superlattice layer 108a includes: performing a first growth process (e.g., MOCVD, MBE, etc.) to form the first semiconductor layer 208 and performing a second growth process (e.g., MOCVD, MBE, etc.) to form the second semiconductor layer 210. In various embodiments, the first and second growth processes are performed at a relatively high temperature within a range of about 950 to 1,200 degrees Celsius and under a pressure within a range of about 30 to 100 mbar. In various embodiments, the first and second growth processes including performing a doping process such that the first and second semiconductor layers 208, 210 comprise one or more dopants (e.g., carbon) with a doping concentration of greater than about 1 e 19 cm⁻³, within a range of about 1 e 19 cm⁻³ to 4 e 19 cm⁻³, of about 3 e 19 cm⁻³, or some other suitable value. In further embodiments, the first growth process includes flowing an aluminum precursor (e.g., trimethylaluminum (TMAl)), a gallium precursor (e.g., trimethylgallium (TMGa)), and a dopant precursor (e.g., C₆H₁₂, CH₄, C₂H₂, C₂H₄, C₃H₈, etc.) over the substrate 102 to form the first semiconductor layer 208 comprising Al_{y}GaN_{1-y} (where y is about 0-0.5, about 0-0.2, or the like) doped with the one or more dopants (e.g., carbon). In an alternative embodiment, the first growth process includes flowing a gallium precursor (e.g., trimethylgallium (TMGa)), a nitride precursor (e.g., ammonia (NH₃)), and a dopant precursor (e.g., C₆H₁₂, CH₄, C₂H₂, C₂H₄, C₃H₈, etc.) over the substrate 102 to form the first semiconductor layer 208 comprising GaN doped with the one or more dopants (e.g., carbon). In some embodiments, the second growth process includes flowing an aluminum precursor (e.g., trimethylaluminum (TMAl)), a nitride precursor (e.g., ammonia (NH₃)), and a dopant precursor (e.g., C₆H₁₂, CH₄, C₂H₂, C₂H₄, C₃H₈, etc.) over the substrate 102 to form the second semiconductor layer 210 comprising AlN doped with the one or more dopants (carbon). In various embodiments, the aforementioned first and second growth processes may be repeated as many times as desired to form any number of pairs of the first and second semiconductor layers 208, 210 over the substrate 102. For example, the aforementioned first and second growth processes may be repeated 10 to 500 times, such that the first superlattice layer 108a comprises 10 to 500 pairs of the first and second semiconductor layers 208, 210.

By virtue of the first superlattice layer 108a being formed at a relatively high temperature (e.g., within a range of about 950 to 1,200 degrees Celsius) the first and second semiconductor layers 208, 210 respectively have a high-quality crystalline structure with a relatively low density of dislocations (e.g., edge dislocation(s), screw dislocation(s), etc.) and/or a relatively low concentration of dangling bonds. As a result, the first superlattice layer 108a may mitigate negative effects (e.g., cracking) due to a lattice and/or CTE mismatch between the substrate 102 and a subsequently formed channel layer (e.g., 114 of FIG. 15).

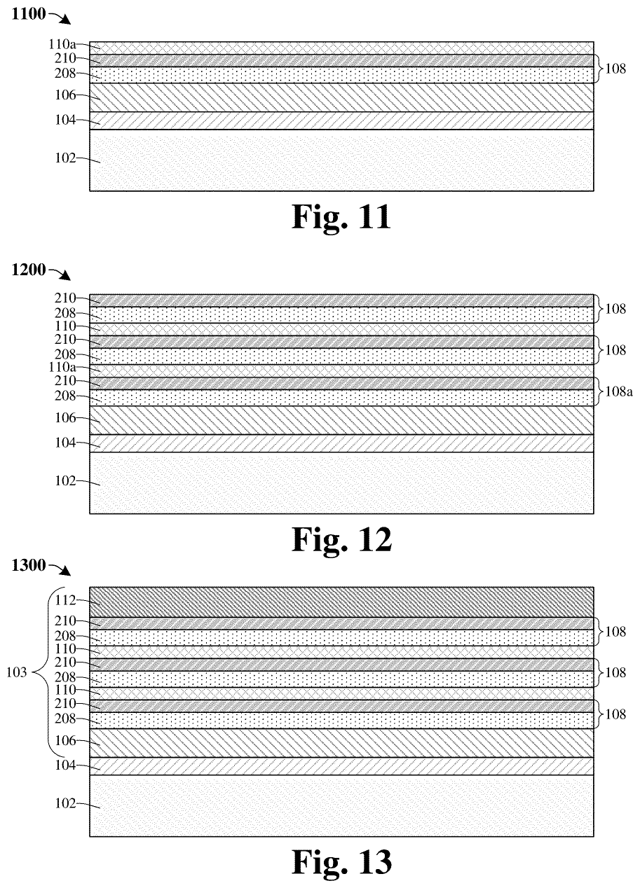

As shown in cross-sectional view 1100 of FIG. 11, a first interlayer buffer layer 110a is formed over the first superlattice layer 108a. In various embodiments, an individual interlayer buffer layer (e.g., configured and/or formed as the first interlayer buffer layer 110a) is formed and/or disposed between each pair of semiconductor layers in the first superlattice layer 108a. In various embodiments, the first interlayer buffer layer 110a comprises AlN, AlGaN, some other group III-V material, or any combination of the foregoing. In various embodiments, the first interlayer buffer layer 110a is formed to a thickness within a range of about 5 to 50 nm or some other suitable value. Further, a doping process (e.g., an in-situ) is performed on the first interlayer buffer layer 110a such that the first interlayer buffer layer 110a comprises one or more dopants (e.g., carbon) with a concentration of about 3 e 19 cm⁻³, greater than about 1 e 19 cm⁻³, within a range of about 2 e 19 cm⁻³ to 4 e 19 cm⁻³, or some other suitable value.

In some embodiments, a process for forming the first interlayer buffer layer 110a includes performing a growth process, such as, for example, MOCVD, MBE, or the like at a relatively low temperature. The relatively low temperature may, for example, be within a range of about 600 to 950 degrees Celsius. Further, the growth process may be performed under a pressure within a range of about 30 to 100 mbar or some other suitable value. In various embodiments, the growth process includes flowing an aluminum precursor (e.g., trimethylaluminum (TMAl)), a gallium precursor (e.g., trimethylgallium (TMGa)), and a dopant precursor (e.g., C₆H₁₂, CH₄, C₂H₂, C₂H₄, C₃H₈, etc.) over the substrate 102. In another embodiment, the growth process includes flowing an aluminum precursor (e.g., trimethylaluminum (TMAl)), a nitride precursor (e.g., ammonia (NH₃)), and a dopant precursor (e.g., C₆H₁₂, CH₄, C₂H₂, C₂H₄, C₃H₈, etc.) over the substrate 102. In yet further embodiments, the first interlayer buffer layer 110a includes a first buffer layer (e.g., 402 of FIG. 4) comprising AlN stacked with a second buffer layer (e.g., 404 of FIG. 4) comprising AlGaN. In such embodiments, forming the first interlayer buffer layer 110a includes forming the first buffer layer by the aforementioned growth process and subsequently performing the growth process again to form the second buffer layer over the first buffer layer.

By virtue of the first interlayer buffer layer 110a being formed at a relatively low temperature (e.g., within a range of about 600 to 950 degrees Celsius) the first interlayer buffer layer 110a has a relatively high density of dislocations. As a result, the first interlayer buffer layer 110a may mitigate or reduce undesired stress (e.g., high tensile stress) in the first superlattice layer 108a and/or within subsequently formed layers (e.g., channel layer 114 of FIG. 15) during fabrication of the high voltage device. This, in part, mitigates cracking of the subsequently formed layers and increases an overall performance of the high voltage device.

As shown in cross-sectional view 1200 of FIG. 12, additional superlattice layers of a plurality of superlattice layers 108 are formed over substrate 102 and one or more additional interlayer buffer layers of a plurality of interlayer buffer layers 110 are alternatingly formed with the plurality of superlattice layers 108 over the substrate 102. The plurality of superlattice layers 108 includes the first superlattice layer 108a and the plurality of interlayer buffer layers 110 includes the first interlayer buffer layer 110a. In various embodiments, each additional superlattice layer in the plurality of superlattice layers 108 may be formed as illustrated and/or described in FIG. 10. In further embodiments, each additional interlayer buffer layer in the plurality of interlayer buffer layers 110 may be formed as illustrated and/or described in FIG. 11. In some embodiments, the processes of FIG. 10 and/or of FIG. 11 are repeated at least 1 to 10 times.

As shown in cross-sectional view 1300 of FIG. 13, a high resistivity buffer layer 112 is formed over the plurality of superlattice layers 108, thereby forming a buffer structure 103 over the seed layer 104. The high resistivity buffer layer 112 may, for example, be or comprise GaN doped with one or more dopants (e.g., carbon) or some other suitable group III-V material. In various embodiments, a concentration of the one or more dopants (e.g., carbon) within the high resistivity buffer layer 112 is greater than about 8 e 18 cm⁻³ or some other suitable value. In further embodiments, the high resistivity buffer layer 112 is formed to a thickness within a range of about 0.5 to 1.5 um or some other suitable value.

The high resistivity buffer layer 112 may be formed or grown over the plurality of superlattice layers 108 by, for example, MOCVD, MBE, another epitaxial growth process, some other suitable growth or deposition process, or any combination of the foregoing. In various embodiments, the high resistivity buffer layer 112 may be formed at a temperature within a range of about 1,000 to 1,150 degrees Celsius and under a pressure within a range of about 50 to 500 mbar. In yet further embodiments, the high resistivity buffer layer 112 is formed over the plurality of superlattice layers 108 with a dopant precursor (e.g., C₆H₁₂, CH₄, C₂H₂, C₂H₄, C₃H₈, etc.), such that the high resistivity buffer layer 112 comprises the one or more dopants (e.g., carbon).

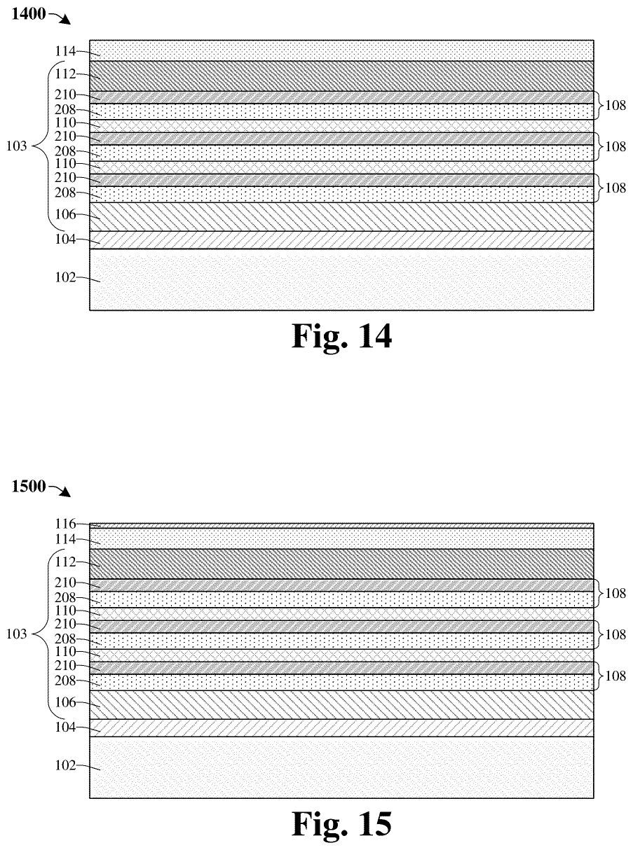

As shown in cross-sectional view 1400 of FIG. 14, a channel layer 114 is formed over the high resistivity buffer layer 112. The channel layer 114 may, for example, be or comprise GaN, undoped GaN, or the like. The channel layer 114 may be formed or grown over the high resistivity buffer layer 112 by, for example, MOCVD, MBE, or some other suitable growth or deposition process. In various embodiments, the channel layer 114 is formed at a temperature within a range of about 1,000 to 1,150 degrees Celsius and under a pressure within a range of about 200 to 600 mbar. In some embodiments, the channel layer 114 is formed to a thickness within a range of about 0.2 to 1 um or some other suitable value.

As shown in cross-sectional view 1500 of FIG. 15, a spacer layer 116 is formed over the channel layer 114. The spacer layer 116 may, for example, be or comprise AlN or some other suitable material. The spacer layer 116 may be formed or grown over the channel layer 114 by, for example, MOCVD, MBE, or some other suitable growth or deposition process. In some embodiments, the spacer layer 116 is formed at a temperature within a range of about 1,050 to 1,200 degrees Celsius and under a pressure within a range of about 50 to 200 mbar. In various embodiments, the spacer layer 116 is formed to a thickness of about 1 nm, within a range of about 0.5 to 1.5 nm or some other suitable value.

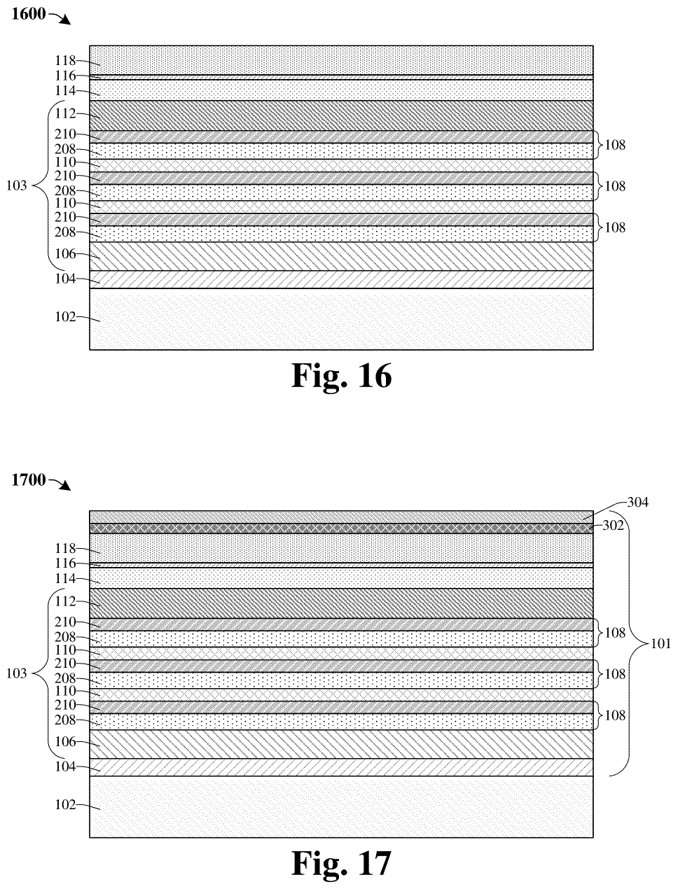

As shown in cross-sectional view 1600 of FIG. 16, an active layer 118 is formed over the spacer layer 116. The active layer 118 may, for example, be or comprise Al_{z}Ga_{1-z}N (where z is within a range of about 0.1-0.5) or some other suitable material. The active layer 118 may be formed or grown over the spacer layer 116 by, for example, MOCVD, MBE, or some other suitable growth or deposition process. In various embodiments, the active layer 118 is formed at a temperature within a range of about 1,050 to 1,200 degrees Celsius and under a pressure within a range or about 50 to 200 mbar. In some embodiments, the active layer 118 is formed to a thickness within a range of about 15 to 30 nm or some other suitable value.

As shown in cross-sectional view 1700 of FIG. 17, a first doped layer 302 and a second doped layer 304 are formed over the active layer 118, thereby defining an epitaxial stack 101. The first doped layer 302 may, for example, be or comprise GaN comprising a first dopant (e.g., magnesium) having a first doping type (e.g., p-type) or some other suitable material. The second doped layer 304 may, for example, be or comprise GaN comprising a second dopant (e.g., silicon) having a second doping type (e.g., n-type) or some other suitable material. In various embodiments, the first doping type is opposite the second doping type. In some embodiments, the first and second doped layers 302, 304 are respectively formed, for example, by MOCVD, MBE, or some other suitable growth or deposition process. In further embodiments, the first and second doped layers 302, 304 are respectively formed at a temperature within a range of about 950 to 1,100 degrees Celsius and under a pressure within a range of about 100 to 500 mbar.

In yet further embodiments, the first and second doped layers 302, 304 are respectively formed to a thickness within a range of about 30 to 100 nm or some other suitable value. In some embodiments, the first doped layer 302 is formed over the active layer 118 with a first dopant precursor (e.g., bis(cyclopentadienyl)magnesium(II) (Cp₂Mg)), such that the first doped layer 302 comprises the first dopant (e.g., magnesium) having a first doping concentration within a range of about 1 e 19 cm⁻³ to 5 e 19 cm⁻³ or some other suitable value. In various embodiments, the second doped layer 304 is formed over the first doped layer 302 with a second dopant precursor (e.g., silane (SiH₄)), such that the second doped layer 304 comprises the second dopant (e.g., silicon) having a second doping concentration within a range of about 1 e 15 cm⁻³ to 1 e 17 cm⁻³ or some other suitable value.

In various embodiments, after forming the epitaxial stack 101 a cool down process is performed on the epitaxial stack 101. In some embodiments, the cool down process includes reducing a temperature of a chamber that the epitaxial stack 101 is deposed in from a high temperature (e.g., 600 degrees Celsius or greater) to room temperature (e.g., about 20 degrees Celsius). A tensile stress of layer(s) in the superlattice layers 108, the high resistivity buffer layer 112, and/or the channel layer 114 may be prone to increase during the cool down process due to a lattice and/or CTE mismatch with the substrate 102. However, by virtue of the interlayer buffer layers 110 being formed at the relatively low temperature, an increase of tensile stress during the cool down process (and other fabrication process(es) and/or during operation) may be mitigated. As a result, tensile stress in the epitaxial stack 101 is reduced, thereby mitigating cracking of the epitaxial stack 101 and increasing an overall performance and reliability of the high voltage device.

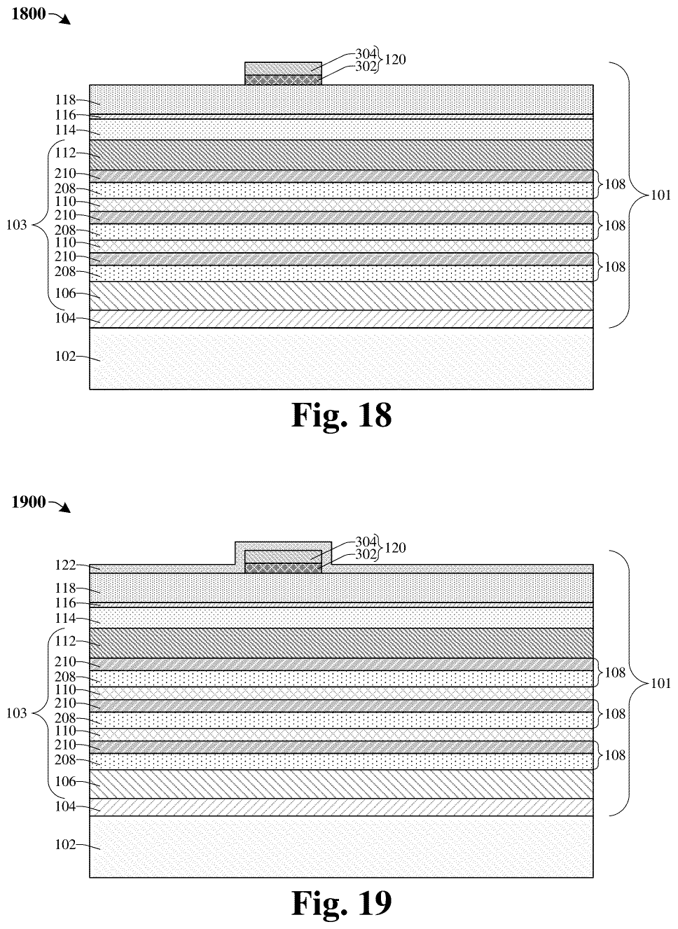

As shown in cross-sectional view 1800 of FIG. 18, a patterning process is performed on the first and second doped layers 302, 304, thereby defining a doped semiconductor structure 120 over the active layer 118. In some embodiments, the patterning process includes: forming a masking layer (not shown) over the second doped layer 304; performing an etching process (e.g., a dry etch process) on the first and second doped layers 302, 304 with the masking layer in place; and performing a removal process to remove the masking layer. In yet further embodiments, after the patterning process further includes performing a wet etch process after the etching process.

As shown in cross-sectional view 1900 of FIG. 19, a passivation layer 122 is formed over the doped semiconductor structure 120 and the active layer 118. The passivation layer 122 may, for example, be or comprise silicon nitride, silicon carbide, another dielectric material, or the like. In various embodiments, the passivation layer 122 is formed over the active layer 118 by a physical vapor deposition (PVD) process, a chemical vapor deposition (CVD) process, an atomic layer deposition (ALD) process, or some other suitable growth or deposition process. In some embodiments, a thickness of the passivation layer 122 is within a range of about 100 to 500 angstroms or some other suitable value.

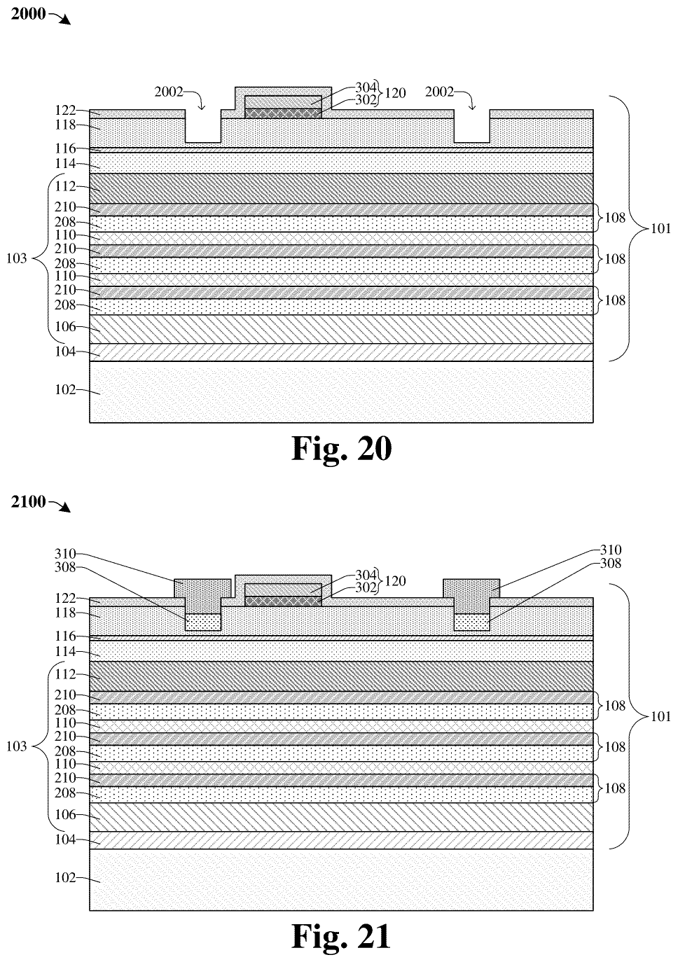

As shown in cross-sectional view 2000 of FIG. 20, a patterning process is performed on the passivation layer 122 and the active layer 118 to form a plurality of openings 2002 on opposing sides of the doped semiconductor structure 120. In some embodiments, the patterning process includes forming a masking layer (not shown) over the passivation layer 122 and performing an etching process (e.g., a dry etch process) on the passivation layer 122 with the masking layer in place. In various embodiments, the masking layer is removed during and/or after the etching process.

As shown in cross-sectional view 2100 of FIG. 21, a first source/drain layer 308 and a second source/drain layer 310 are formed within the openings (2002 of FIG. 20). In some embodiments, a process for forming the first and second source/drain layers 308, 310 includes: depositing (e.g., by PVD, CVD, sputtering, electroplating, etc.) the first source/drain layer 308 over the active layer 118; depositing (e.g., by PVD, CVD, sputtering, electroplating, etc.) the second source/drain layer 310 over the first source/drain layer 308; forming a masking layer (not shown) over the second source/drain layer 310; and performing an etching process (e.g., a dry etch process) on the first and second source/drain layers 308, 310 with the masking layer in place. The first source/drain electrode layer 308 may, for example, be or comprise titanium, tantalum, nickel, some other metal, or any combination of the foregoing. The second source/drain layer 310 may, for example, be or comprise aluminum, tungsten, some other metal, or any combination of the foregoing.

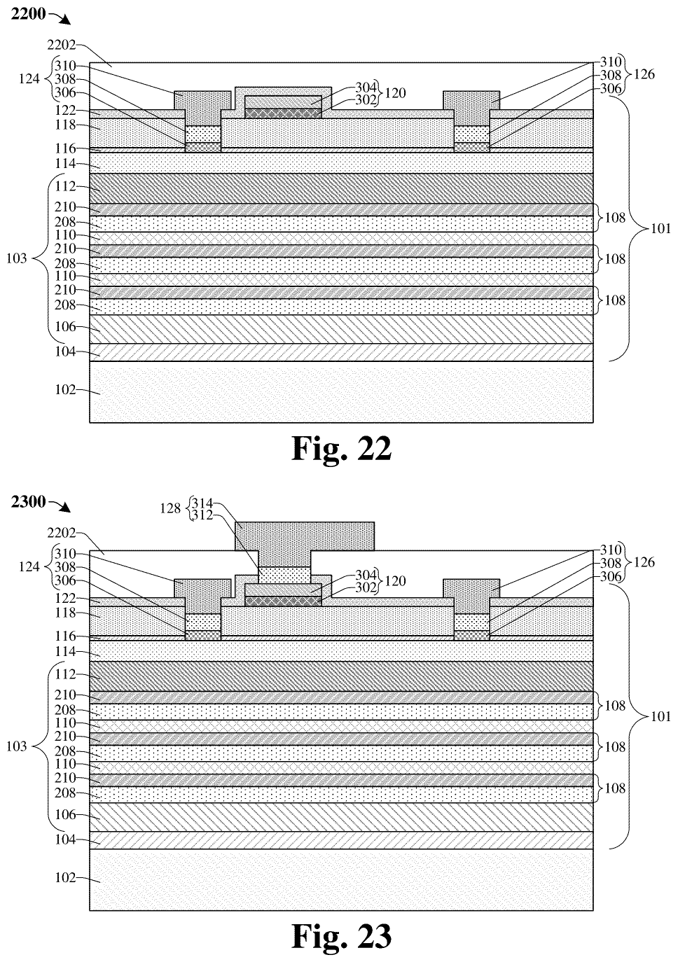

As shown in cross-sectional view 2200 of FIG. 22, a silicide layer 306 is formed under the first source/drain layer 308, thereby defining source/drain electrodes 124, 126 disposed on opposing sides of the doped semiconductor structure 120. In various embodiments, a process for forming the silicide layer 306 includes performing an annealing process such that at least a portion of the first source/drain layer 308 is converted into the silicide layer 306. In some embodiments, the annealing process is performed at a temperature within a range of about 600 to 950 degrees Celsius or some other suitable value. The silicide layer 306 may, for example, be or comprise titanium silicide, tantalum silicide, nickel silicide, some other conductive material, or any combination of the foregoing. Further, as shown in FIG. 22, a first dielectric layer 2202 is formed over the passivation layer 122. In some embodiments, the first dielectric layer 2202 is formed over the passivation layer 122 by, for example, a CVD process, a PVD process, an ALD process, or some other suitable growth or deposition process. The first dielectric layer 2202 may, for example, be or comprise silicon dioxide or another dielectric material and/or may have a thickness within a range of about 5,000 to 20,0000 angstroms or some other suitable value. Further, after depositing the first dielectric layer 2202 over the passivation layer 122, a planarization process (e.g., a chemical mechanical planarization (CMP) process) may be performed on the first dielectric layer 2202.

As shown in cross-sectional view 2300 of FIG. 23, a gate electrode 128 is formed over the doped semiconductor structure 120. In some embodiments, the gate electrode 128 comprises a first gate electrode layer 312 stacked with a second gate electrode layer 314. In various embodiments, a process for forming the gate electrode 128 includes: patterning the first dielectric layer 2202 and the passivation layer 122 to form a gate electrode opening over the doped semiconductor structure 120; depositing (e.g., by PVD, CVD, sputtering, electroplating, etc.) the first gate electrode layer 312 over the first dielectric layer 2202 and within the gate electrode opening; depositing (e.g., by PVD, CVD, sputtering, electroplating, etc.) the second gate electrode layer 314 over the first gate electrode layer 312; and performing a patterning process on the first and second gate electrode layers 312, 314. The first gate electrode layer 312 may, for example, be or comprise titanium nitride, tantalum nitride, another conductive material, or any combination of the foregoing. The second gate electrode layer 314 may, for example, be or comprise aluminum, tungsten, some other metal, or any combination of the foregoing.

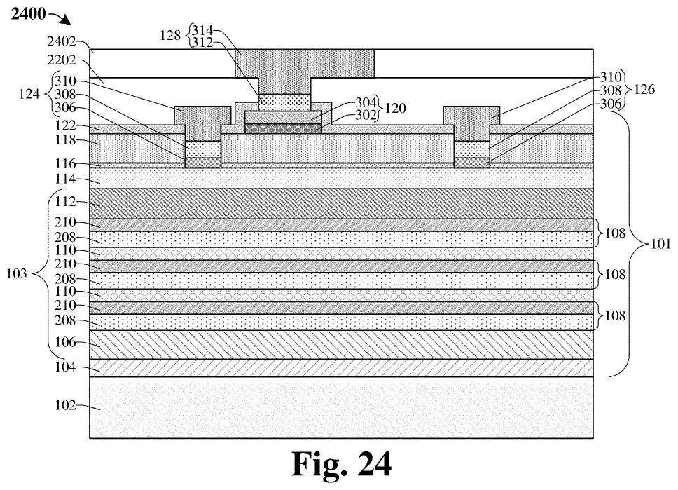

As shown in cross-sectional view 2400 of FIG. 24, a second dielectric layer 2402 is formed over the first dielectric layer 2202. In some embodiments, the second dielectric layer 2402 is formed over the first dielectric layer 2202 by, for example, a CVD process, a PVD process, an ALD process, or some other suitable growth or deposition process. The second dielectric layer 2402 may, for example, be or comprise silicon dioxide or some other suitable dielectric material.

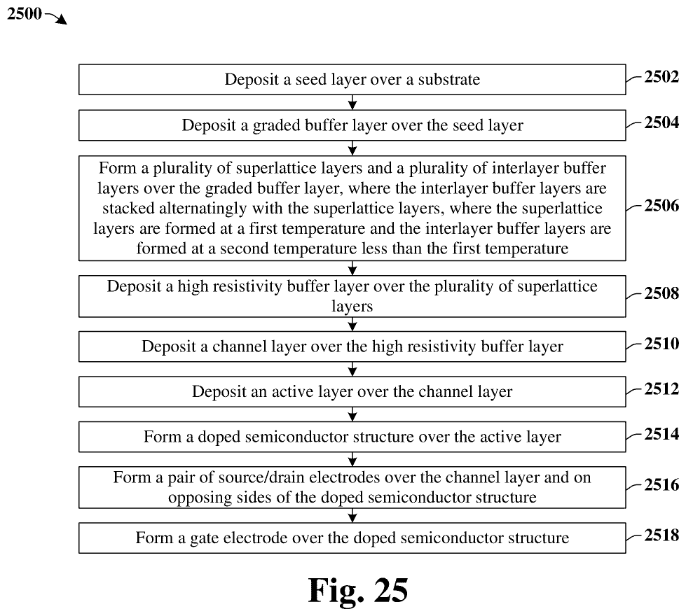

FIG. 25 illustrates a flowchart of some embodiments of a method 2500 for forming a high voltage device including interlayer buffer layers disposed between adjacent superlattice layers. Although the method 2500 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2502, a seed layer is deposited over a substrate. FIG. 8 illustrates cross-sectional view 800 corresponding to some embodiments of act 2502.

At act 2504, a graded buffer layer is deposited over the seed layer. FIG. 9 illustrates cross-sectional view 900 corresponding to some embodiments of act 2504.

At act 2506, a plurality of superlattice layers and a plurality of interlayer buffer layers are formed over the graded buffer layer, where the interlayer buffer layers are stacked alternatingly with the superlattice layers. The superlattice layers are formed at a first temperature and the interlayer buffer layers are formed at a second temperature less than the first temperature. FIGS. 10-12 illustrate cross-sectional views 1000-1200 corresponding to some embodiments of act 2506.

At act 2508, a high resistivity buffer layer is deposited over the plurality of superlattice layers. FIG. 13 illustrates cross-sectional view 1300 corresponding to some embodiments of act 2508.

At act 2510, a channel layer is deposited over the high resistivity buffer layer. FIG. 14 illustrates cross-sectional view 1400 corresponding to some embodiments of act 2510.

At act 2512, an active layer is deposited over the channel layer. FIG. 16 illustrates cross-sectional view 1600 corresponding to some embodiments of act 2512.

At act 2514, a doped semiconductor structure is formed over the active layer. FIGS. 17 and 18 illustrates cross-sectional views 1700 and 1800 corresponding to some embodiments of act 2514.

At act 2516, a pair of source/drain electrodes are formed over the channel layer on opposing sides of the doped semiconductor structure. FIGS. 20-22 illustrate various cross-sectional views corresponding to some embodiments of act 2516.

At act 2518, a gate electrode is formed over the doped semiconductor structure. FIG. 23 illustrates cross-sectional view 2300 corresponding to some embodiments of act 2518.

Accordingly, in some embodiments, the present disclosure relates to a semiconductor device comprising a plurality of interlayer buffer layers stacked alternatingly with a plurality of superlattice layers.

In some embodiments, the present application provides a semiconductor device, including: a plurality of superlattice layers disposed over a substrate, wherein the plurality of superlattice layers comprise a first superlattice layer overlying a second superlattice layer; a channel layer overlying the plurality of superlattice layers; an active layer overlying the channel layer; and a first interlayer buffer layer disposed directly between the first superlattice layer and the second superlattice layer, wherein the first interlayer buffer layer comprises a first density of dislocations greater than a second density of dislocations in the first superlattice layer. In an embodiment, the first interlayer buffer layer is configured to reduce tensile stress on the plurality of superlattice layers and/or the channel layer. In an embodiment, the plurality of superlattice layers respectively comprise one or more pairs of semiconductor layers, wherein the one or more pairs of semiconductor layers comprise a first semiconductor layer stacked with a second semiconductor layer, wherein lattice constants of the first and second semiconductor layers are mismatched. In an embodiment, the first interlayer buffer layer and the second semiconductor layer comprise a first semiconductor material. In an embodiment, the first semiconductor material is aluminum nitride. In an embodiment, a thickness of the first interlayer buffer layer is greater than a thickness of the first semiconductor layer, wherein a thickness of the second semiconductor layer is greater than the thickness of the first interlayer buffer layer. In an embodiment, the semiconductor device further includes: a seed layer disposed on the substrate, wherein the seed layer comprises a first group III-V material; a graded buffer layer disposed between the seed layer and the plurality of superlattice layers, wherein the graded buffer layer comprises a second group III-V material different from the first group III-V material; a high resistivity buffer layer disposed between the plurality of superlattice layers and the channel layer, wherein the high resistivity buffer layer comprises a third group III-V material; and a doped semiconductor structure over the active layer, wherein the doped semiconductor structure comprises the third group III-V material. In an embodiment, the first interlayer buffer layer comprises the first group III-V material, wherein a thickness of the first interlayer buffer layer is less than a thickness of the seed layer and a thickness of the graded buffer layer.

In various embodiments, the present application provides an a semiconductor device, including: a seed layer overlying a substrate and comprising aluminum nitride (AlN); a channel layer overlying the seed layer and comprising gallium nitride (GaN); an active layer overlying the channel layer and comprising aluminum gallium nitride (AlGaN); and a buffer structure disposed between the channel layer and the seed layer, wherein the buffer structure comprises a plurality of superlattice layers alternatingly stacked with a plurality of interlayer buffer layers, wherein the plurality of superlattice layers respectively comprise a first semiconductor layer stacked with a second semiconductor layer, wherein the second semiconductor layer comprises AlN, wherein the plurality of interlayer buffer layers comprises AlN and/or AlGaN, and wherein the plurality of interlayer buffer layers comprise one or more dopants. In an embodiment, the plurality of superlattice layers comprise the one or more dopants, and wherein a concentration of the one or more dopants in the plurality of interlayer buffer layers and the plurality of superlattice layers is greater than about 1 e 19 cm⁻³. In an embodiment, wherein the plurality of interlayer buffer layers respectively comprise a first buffer layer stacked with a second buffer layer, wherein the first buffer layer comprises AlN and the second buffer layer comprises AlGaN. In an embodiment, the semiconductor device further includes: a doped semiconductor structure overlying the active layer, wherein the doped semiconductor structure comprises GaN; a gate electrode overlying the doped semiconductor structure; and a pair of source/drain electrodes overlying the channel layer and disposed on opposing sides of the gate electrode, wherein the pair of source/drain electrodes extends through the active layer to the channel layer. In an embodiment, the buffer structure further comprises a graded buffer layer disposed on the seed layer and a high resistivity buffer layer disposed on the channel layer, wherein the plurality of interlayer buffer layers comprises a lower interlayer buffer layer and an upper interlayer buffer layer, wherein the lower interlayer buffer layer is disposed between the graded buffer layer and a bottommost superlattice layer in the plurality of superlattice layers, and wherein the upper interlayer buffer layer is disposed between the high resistivity buffer layer an a topmost superlattice layer in the plurality of superlattice layers. In an embodiment, the superlattice layers respectively comprise about 10 to 500 pairs of the first semiconductor layer and the second semiconductor layer, wherein an individual interlayer buffer layer from the plurality of interlayer buffer layers is disposed between each adjacent pair of the first and second semiconductor layers. In an embodiment, a density of dislocations in the plurality of interlayer buffer layers decreases as a distance from the substrate increases.

In some embodiments, the present application provides a method for forming a semiconductor device, the method includes: forming a seed layer over a substrate; forming a plurality of superlattice layers and a plurality of interlayer buffer layers over the seed layer, wherein the interlayer buffer layers are stacked alternatingly with the superlattice layers, wherein the superlattice layers are formed at a first temperature and the interlayer buffer layers are formed at a second temperature less than the first temperature; forming a channel layer over the plurality of superlattice layers; and forming an active layer over the channel layer. In an embodiment, the superlattice layers respectively have a first density of dislocations and the interlayer buffer layers respectively have a second density of dislocations greater than the first density of dislocations. In an embodiment, the method further includes performing a cool down process after forming the active layer, wherein the cool down process comprises reducing a temperature of a chamber the substrate is disposed in from a high temperature to a low temperature, wherein the interlayer buffer layers are configured to reduce tensile stress on the channel layer and/or the plurality of superlattice layers during the cooling process. In an embodiment, the first temperature is within a range of about 950 to 1,200 degrees Celsius, wherein the second temperature range is within a range of about 600 to 950 degrees Celsius. In an embodiment, the plurality of interlayer buffer layers includes a first interlayer buffer layer and a second interlayer buffer layer overlying the first interlayer buffer layer, wherein the first interlayer buffer layer is formed at a lower temperature than the second interlayer buffer layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of superlattice layers disposed over a substrate, wherein the plurality of superlattice layers comprise a first superlattice layer overlying a second superlattice layer;
a channel layer overlying the plurality of superlattice layers;
an active layer overlying the channel layer; and
a first interlayer buffer layer disposed directly between the first superlattice layer and the second superlattice layer, wherein the first interlayer buffer layer comprises a first density of dislocations greater than a second density of dislocations in the first superlattice layer.

2. The semiconductor device of claim 1, wherein the first interlayer buffer layer is configured to reduce tensile stress on the plurality of superlattice layers and/or the channel layer.

3. The semiconductor device of claim 1, wherein the plurality of superlattice layers respectively comprise one or more pairs of semiconductor layers, wherein the one or more pairs of semiconductor layers comprise a first semiconductor layer stacked with a second semiconductor layer, wherein lattice constants of the first and second semiconductor layers are mismatched.

4. The semiconductor device of claim 3, wherein the first interlayer buffer layer and the second semiconductor layer comprise a first semiconductor material.

5. The semiconductor device of claim 4, wherein the first semiconductor material is aluminum nitride.

6. The semiconductor device of claim 3, wherein a thickness of the first interlayer buffer layer is greater than a thickness of the first semiconductor layer, wherein a thickness of the second semiconductor layer is greater than the thickness of the first interlayer buffer layer.

7. The semiconductor device of claim 1, further comprising:
a seed layer disposed on the substrate, wherein the seed layer comprises a first group III-V material;
a graded buffer layer disposed between the seed layer and the plurality of superlattice layers, wherein the graded buffer layer comprises a second group III-V material different from the first group III-V material;
a high resistivity buffer layer disposed between the plurality of superlattice layers and the channel layer, wherein the high resistivity buffer layer comprises a third group III-V material; and
a doped semiconductor structure over the active layer, wherein the doped semiconductor structure comprises the third group III-V material.

8. The semiconductor device of claim 7, wherein the first interlayer buffer layer comprises the first group III-V material, wherein a thickness of the first interlayer buffer layer is less than a thickness of the seed layer and a thickness of the graded buffer layer.

9. A semiconductor device, comprising:
a seed layer overlying a substrate and comprising aluminum nitride (AlN);
a channel layer overlying the seed layer and comprising gallium nitride (GaN);
an active layer overlying the channel layer and comprising aluminum gallium nitride (AlGaN); and
a buffer structure disposed between the channel layer and the seed layer, wherein the buffer structure comprises a plurality of superlattice layers alternatingly stacked with a plurality of interlayer buffer layers, wherein the plurality of superlattice layers respectively comprise a first semiconductor layer stacked with a second semiconductor layer, wherein the second semiconductor layer comprises AlN, wherein the plurality of interlayer buffer layers comprises AlN and/or AlGaN, and wherein the plurality of interlayer buffer layers comprise one or more dopants.

10. The semiconductor device of claim 9, wherein the plurality of superlattice layers comprise the one or more dopants, and wherein a concentration of the one or more dopants in the plurality of interlayer buffer layers and the plurality of superlattice layers is greater than about 1 e 19 cm⁻³.

11. The semiconductor device of claim 9, wherein the plurality of interlayer buffer layers respectively comprise a first buffer layer stacked with a second buffer layer, wherein the first buffer layer comprises AlN and the second buffer layer comprises AlGaN.

12. The semiconductor device of claim 9, further comprising:
a doped semiconductor structure overlying the active layer, wherein the doped semiconductor structure comprises GaN;
a gate electrode overlying the doped semiconductor structure; and
a pair of source/drain electrodes overlying the channel layer and disposed on opposing sides of the gate electrode, wherein the pair of source/drain electrodes extends through the active layer to the channel layer.

13. The semiconductor device of claim 9, wherein the buffer structure further comprises a graded buffer layer disposed on the seed layer and a high resistivity buffer layer disposed on the channel layer, wherein the plurality of interlayer buffer layers comprises a lower interlayer buffer layer and an upper interlayer buffer layer, wherein the lower interlayer buffer layer is disposed between the graded buffer layer and a bottommost superlattice layer in the plurality of superlattice layers, and wherein the upper interlayer buffer layer is disposed between the high resistivity buffer layer an a topmost superlattice layer in the plurality of superlattice layers.

14. The semiconductor device of claim 9, wherein the superlattice layers respectively comprise about 10 to 500 pairs of the first semiconductor layer and the second semiconductor layer, wherein an individual interlayer buffer layer from the plurality of interlayer buffer layers is disposed between each adjacent pair of the first and second semiconductor layers.

15. The semiconductor device of claim 9, wherein a density of dislocations in the plurality of interlayer buffer layers decreases as a distance from the substrate increases.

16. A method for forming a semiconductor device, comprising:
forming a seed layer over a substrate;
forming a plurality of superlattice layers and a plurality of interlayer buffer layers over the seed layer, wherein the interlayer buffer layers are stacked alternatingly with the superlattice layers, wherein the superlattice layers are formed at a first temperature and the interlayer buffer layers are formed at a second temperature less than the first temperature;
forming a channel layer over the plurality of superlattice layers; and
forming an active layer over the channel layer.

17. The method of claim 16, wherein the superlattice layers respectively have a first density of dislocations and the interlayer buffer layers respectively have a second density of dislocations greater than the first density of dislocations.

18. The method of claim 16, further comprising:
performing a cool down process after forming the active layer, wherein the cool down process comprises reducing a temperature of a chamber the substrate is disposed in from a high temperature to a low temperature, wherein the interlayer buffer layers are configured to reduce tensile stress on the channel layer and/or the plurality of superlattice layers during the cooling process.

19. The method of claim 16, wherein the first temperature is within a range of about 950 to 1,200 degrees Celsius, wherein the second temperature range is within a range of about 600 to 950 degrees Celsius.

20. The method of claim 16, wherein the plurality of interlayer buffer layers includes a first interlayer buffer layer and a second interlayer buffer layer overlying the first interlayer buffer layer, wherein the first interlayer buffer layer is formed at a lower temperature than the second interlayer buffer layer.
